(19) United States
(12) Patent Application Publication
(10) Pub. No.: US 2021/0183905 A1
(43) Pub. Date: Jun. 17, 2021

(54) ARRAY SUBSTRATE AND MANUFACTURING METHOD THEREOF

(71) Applicant: Wuhan China Star Optoelectronics Semiconductor Display Technology Co., Ltd., Wuhan, Hubei (CN)

(72) Inventor: Cheng CHEN, Wuhan, Hubei (CN)

(21) Appl. No.: 16/768,949

(22) PCT Filed: Feb. 13, 2020
(86) PCT No.: PCT/CN2020/075100

§ 371 Date: Jun. 2, 2020

(30) Foreign Application Priority Data
Dec. 12, 2019 (CN) 201911272740.X

(51) Int. Cl. H01L 27/12; H01L 27/32

(52) U.S. Cl. CPC H01L 27/1222; H01L 27/3258; H01L 27/1262

(57) ABSTRACT

The invention provides an array substrate and a manufacturing method thereof. The array substrate includes a display area and a non-display area. The non-display area has a bonding area and a fan-out area, and the fan-out area is disposed between the display area and the bonding area. The array substrate further includes a thin-film transistor structure layer, including a gate layer and a source-drain electrode layer. A material of the gate layer and the source-drain electrode layer includes at least one of titanium, aluminum, or titanium aluminum alloy.

### FIELD OF INVENTION

The invention relates to the field of display, and in particular, to an array substrate and a method of manufacturing the same.

### BACKGROUND OF INVENTION

Organic light-emitting diode (OLED) is becoming more widely used due to its advantages such as lightweight, self-emission, wide viewing angles, low driving voltage, high luminous efficiency, low power consumption, and fast response times. In particular, flexible OLED display devices have characteristics of bendability and portability, so they have become a main field of research and development in the field of display technology. At present, high-end mobile phones demand higher brightness uniformity. How to improve the brightness uniformity of a screen is a focus direction for major manufacturers.

### TECHNICAL PROBLEM

In order to solve the above technical problems, the present invention provides an array substrate and a manufacturing method thereof, which are used to solve the technical problem that the brightness uniformity of a screen cannot be improved in the prior art.

### SUMMARY OF INVENTION

In order to solve the above technical problems, the technical solutions provided are: An array substrate, wherein the array substrate includes a display area and a non-display area surrounding the display area, the non-display area has a bonding area and a fan-out area positioned between the bonding area and the display area, the array substrate further includes a thin-film transistor structure layer including a gate layer and a source-drain electrode layer, and material of the gate layer and the source-drain electrode layer includes at least one of titanium, aluminum, and titanium aluminum alloy.

Further, the thin-film transistor structure layer includes: a substrate extending from the display area to the non-display area; a barrier layer disposed on the substrate and extending from the display area to the non-display area; a buffer layer disposed on the barrier layer and extending from the display area to the non-display area; an active layer disposed on the buffer layer of the display area; a first insulating layer disposed on the buffer layer and covering the active layer and extending to the non-display area; the gate layer including a first gate layer and a second gate layer; the first gate layer disposed on the first insulating layer; a second insulating layer disposed on the first insulating layer and covering the first gate layer and extending to the non-display area; the second gate layer disposed on the second insulating layer; a third insulating layer disposed on the second insulating layer and covering the second gate layer and extending to the non-display area; wherein the source-drain electrode layer includes: a first source-drain electrode layer disposed on the third insulating layer of the display area and penetrating the third insulating layer, the second insulating layer, and the first insulating layer and connected to the active layer; a second source-drain electrode layer disposed on the third insulating layer in the fan-out area and penetrating the third insulating layer and the second insulating layer and connected to the first gate layer and the second gate layer; an opening defined in the bonding area, and the opening penetrating the third insulating layer, the second insulating layer, the first insulating layer, the buffer layer, and a portion of the barrier layer; and a planarization layer disposed on the third insulating layer and covering the source-drain electrode layer and extending to the non-display area.

Further, the first gate layer includes: a first metal segment disposed in the display area and corresponding to the active layer; a second metal segment disposed on the first insulating layer in the fan-out area; and a third metal segment disposed in the bonding area and extending from the first insulating layer to an inner wall of the opening.

Further, the second gate layer includes: a fourth metal segment disposed in the display area and corresponding to the active layer; a fifth metal segment disposed on the second insulating layer in the fan-out area; a sixth metal segment disposed in the bonding area and extending from the second insulating layer to the inner wall of the opening.

The invention also provides a method of manufacturing an array substrate. The array substrate includes a display area and a non-display area surrounding the display area, the non-display area has a bonding area and a fan-out area positioned between the bonding area and the display area, further including: Step 1, forming a thin-film transistor structure layer, the thin-film transistor structure layer including a gate layer and a source-drain electrode layer, and material of the gate layer and the source-drain electrode layer including at least one of titanium, aluminum, and titanium aluminum alloy.

Further, in the Step 1, the specific manufacturing steps of the thin-film transistor structure layer include: Step 101, providing a substrate; Step 102, depositing a barrier layer on the substrate; Step 103, depositing a buffer layer on the barrier layer; Step 104, forming an active layer and a first insulating layer on the buffer layer in the display area, wherein the first insulating layer covers the active layer and extends to the non-display area;

Step 105, forming an opening by etching in the bonding area, the opening penetrating through the first insulating layer, the buffer layer, and a portion of the barrier layer in the bonding area; Step 106, forming a first gate layer on the first insulating layer, wherein forming the first gate layer includes forming a first metal segment on the display area corresponding to the active layer, forming a second metal segment in the fan-out area and forming a third metal segment in the bonding area, the third metal segment extending from the first insulating layer and covering the inner wall of the opening; Step 107, depositing a second insulating layer on the first insulating layer, wherein the second insulating layer covers the first gate layer and extends to the non-display area; Step 108, forming a second gate layer on the second insulating layer; Step 109, depositing a third insulating layer on the second insulating layer, wherein the third insulating layer covers the second gate layer and extends to the non-display area; Step 110, etching the second insulating layer and the third insulating layer at a position corresponding to the opening in the bonding area, and filling the opening after etching with an organic substance to form an organic layer; Step 111, forming a first via-hole by etching the third insulating layer, the second insulating layer, and the first insulating layer at a position corresponding to the active layer in the display area and forming a second via-hole by etching the third insulating layer and the second insulating layer in the fan-out area; Step 112, depositing a first source-drain electrode layer on the third insulating layer corresponding to the first via-hole, the first source-drain electrode layer electrically connected to the active layer through the first via-hole, and depositing a second source-drain electrode layer corresponding to the second via-hole, the second source-drain electrode layer electrically connected to the first gate layer and the second gate layer through the second via-hole, and forming a third source-drain electrode layer on the organic layer in the bonding area; and Step 113, forming a planarization layer on the third insulating layer and extending the planarization layer to the non-display area.

Further, in the Step 1, the specific manufacturing steps of the thin-film transistor structure layer include: Step 101, providing a substrate; Step 102, depositing a barrier layer on the substrate; Step 103, depositing a buffer layer on the barrier layer; Step104, forming an active layer and a first insulating layer on the buffer layer in the display area, wherein the first insulating layer covers the active layer and extends to the non-display area; Step 105, forming an opening by etching in the bonding area, the opening penetrating the first insulating layer, the buffer layer, and a portion of the barrier layer in the bonding area; Step 106, forming a first gate layer on the first insulating layer, wherein forming the first gate layer includes forming a first metal segment corresponding to the active layer in the display area, forming a second metal segment in the fan-out area and forming a third metal segment in the bonding area, the third metal segment covering the inner wall of the opening from the first insulating layer; Step 107, depositing a second insulating layer on the first insulating layer, wherein the second insulating layer covers the first gate layer and extends to the non-display area; Step 108, forming a second gate layer on the second insulating layer; Step 109, depositing a third insulating layer on the second insulating layer, wherein the third insulating layer covers the second gate layer and extends to the non-display area; Step 110, etching the second insulating layer and the third insulating layer at a position corresponding to the opening in the bonding area and simultaneously etching the third insulating layer, the second insulating layer, and the first insulating layer at a position corresponding to the active layer in the display area to form a first via-hole and etching the third insulating layer and the second insulating layer in the fan-out area to form a second via-hole; Step 111, filling the opening after etching with an organic substance to form an organic layer; Step 112, depositing a first source-drain electrode layer on the third insulating layer at a position corresponding to the first via-hole, the first source-drain electrode layer electrically connected to the active layer through the first via-hole, and depositing a second source-drain electrode layer at a position corresponding to the second via-hole, the second source-drain electrode layer electrically connected to the first gate layer and the second gate layer through the second via-hole, and forming a third source-drain electrode layer on the organic layer in the bonding area; and Step 113, forming a planarization layer on the third insulating layer and extending to the non-display area.

Further, in the Step 1, the specific manufacturing steps of the thin-film transistor structure layer include: Step 101, providing a substrate; Step 102, depositing a barrier layer on the substrate; Step 103, depositing a buffer layer on the barrier layer; Step 104, forming an active layer and a first insulating layer on the buffer layer in the display area, wherein the first insulating layer covers the active layer and extends to the non-display area; Step 105, forming a first gate layer on the first insulating layer; Step 106, depositing a second insulating layer on the first insulating layer, wherein the second insulating layer covers the first gate layer and extends to the non-display area; Step 107, forming an opening by etching in the bonding area, the opening penetrating through the second insulating layer, the first insulating layer, the buffer layer, and a portion of the barrier layer in the bonding area; Step 108, forming a second gate layer on the second insulating layer, wherein forming the second gate layer includes forming a fourth metal segment on the display area corresponding to the active layer, forming a fifth metal segment in the fan-out area, and forming a sixth metal segment in the bonding area, the sixth metal segment covering the inner wall of the opening from the second insulating layer; Step 109, depositing a third insulating layer on the second insulating layer, wherein the third insulating layer covers the second gate layer and extends to the non-display area; Step 110, etching the third insulating layer at a position corresponding to the opening in the bonding area, and filling the opening after etching with an organic substance to form an organic layer; Step 111, forming a first via-hole by etching the third insulating layer, the second insulating layer, and the first insulating layer at a position corresponding to the active layer in the display area and forming a second via-hole by etching the third insulating layer and the second insulating layer in the fan-out area; Step 112, depositing a first source-drain electrode layer on the third insulating layer corresponding to the first via-hole, the first source-drain electrode layer electrically connected to the active layer through the first via-hole, and depositing a second source-drain electrode layer corresponding to the second via-hole, the second source-drain electrode layer electrically connected to the first gate layer and the second gate layer through the second via-hole, and forming a third source-drain electrode layer on the organic layer in the bonding area; and Step 113, forming a planarization layer on the third insulating layer and extending the planarization layer to the non-display area.

Further, in the Step 1, the specific manufacturing steps of the thin-film transistor structure layer include: Step 101, providing a substrate; Step 102, depositing a barrier layer on the substrate; Step 103, depositing a buffer layer on the barrier layer; Step 104, forming an active layer and a first insulating layer on the buffer layer in the display area, wherein the first insulating layer covers the active layer and extends to the non-display area; Step 105, forming a first gate layer on the first insulating layer; Step 106, depositing a second insulating layer on the first insulating layer, wherein the second insulating layer covers the first gate layer and extends to the non-display area; Step 107, forming an opening by etching in the bonding area, the opening penetrating through the second insulating layer, the first insulating layer, the buffer layer, and a portion of the barrier layer in the bonding area; Step 108, forming a second gate layer on the second insulating layer, wherein forming the second gate layer includes forming a fourth metal segment on the display area corresponding to the active layer, forming a fifth metal segment in the fan-out area, and forming a sixth metal segment in the bonding area, the sixth metal segment covering the inner wall of the opening from the second insulating layer; Step 109, depositing a third insulating layer on the second insulating layer, wherein the third insulating layer covers the second gate layer and extends to the non-display area; Step 110, etching the third insulating layer at a position corresponding to the opening in the bonding area and simultaneously etching the third insulating layer, the second insulating layer, and the first insulating layer at a position corresponding to the active layer in the display area to form a first via-hole and etching the third insulating layer and the second insulating layer in the fan-out area to form a second via-hole; Step 111, filling the opening after etching with an organic substance to form an organic layer; Step 112, depositing a first source-drain electrode layer on the third insulating layer at a position corresponding to the first via-hole, the first source-drain electrode layer electrically connected to the active layer through the first via-hole, and depositing a second source-drain electrode layer at a position corresponding to the second via-hole, the second source-drain electrode layer electrically connected to the first gate layer and the second gate layer through the second via-hole, and forming a third source-drain electrode layer on the organic layer in the bonding area; and Step 113, forming a planarization layer on the third insulating layer and extending to the non-display area.

Further, it also includes: Step 2, forming a via-hole on the planarization layer corresponding to the first source-drain electrode layer and depositing an anode layer on the planarization layer, and the anode layer connected to the first source-drain electrode layer through the via-hole; Step 3, depositing a pixel definition layer on the planarization layer, wherein the pixel definition layer covers the anode layer; and Step 4, forming a light-emitting hole in the pixel definition layer corresponding to an area of the anode layer, and a bottom surface of the light-emitting hole being completely disposed on the anode layer.

### BENEFICIAL EFFECT

In the array substrate and the manufacturing method thereof provided by the present invention, the gate layer and the source-drain electrode layer on the array substrate are made of the same material, such as aluminum, titanium, titanium aluminum alloy, and other low-resistance and bend-resistant metals, which improves the electrical conductivity and bending characteristics of metal traces. In the bonding area of the array substrate, the gate layer is disposed below the organic layer and is closer to the neutral plane, which reduces the risk of disconnection in the bonding area. The inorganic film layer is patterned by using the gate layer as a mask, which saves costs and solves the problem of poor adhesion of metal trace on the etched flexible substrate.

### DESCRIPTION OF DRAWINGS

The following describes the specific implementation of the present application in detail with reference to the drawings so that the technical solution and other beneficial effects of the application are clear.

FIG. 1 is a schematic diagram of an array substrate in embodiment 1.

FIG. 2 is a schematic diagram of an array substrate in step S109 of embodiment 1.

FIG. 3 is a schematic diagram of an array substrate in step S110 of embodiment 1.

FIG. 4 is a schematic diagram of the array substrate in step S110 after replacement in embodiment 1.

FIG. 5 is a schematic diagram of an array substrate in embodiment 2.

FIG. 6 is a schematic diagram of an array substrate in step S109 of embodiment 2.

FIG. 7 is a schematic diagram of an array substrate in step S110 of embodiment 2.

FIG. 8 is a schematic diagram of an array substrate in step S110 after replacement in embodiment 2.

### REFERENCE NUMERALS

110 thin-film transistor layer; 120 anode layer; 130 pixel definition layer; 1101 substrate; 1102 barrier layer; 1103 buffer layer; 1104 active layer; 1105 first insulating layer; 1106 first gate layer; 1107 second insulating layer; 1108 second gate layer; 1109 third insulating layer; 1110 source-drain electrode layer; 1111 planarization layer; 101 display area; 102 non-display area; 1021 fan-out area; 1022 bonding area; 11061 first metal segment; 11062 second metal segment; 11063 third metal segment; 10221 opening; 11101 first source-drain electrode layer; 11102 second source-drain electrode layer; 11103 third source-drain electrode layer; 11081 fourth metal segment; 11082 fifth metal segment; 11083 sixth metal segment; 131 pixel opening; 132 retaining wall.

### DETAILED DESCRIPTION OF PREFERRED EMBODIMENTS

The technical solutions in the embodiments of the present application will be clearly and completely described below with reference to the drawings in the embodiments of the present application. Obviously, the embodiments are only a part of the embodiments of the present application, but not all the embodiments. Based on the embodiments in the present application, all other embodiments obtained by those skilled in the art without creative work fall into the protection scope of the present application.

### Embodiment 1

In the present embodiment, an array substrate of the present invention includes a thin-film transistor layer 110, an anode layer 120, and a pixel definition layer 130.

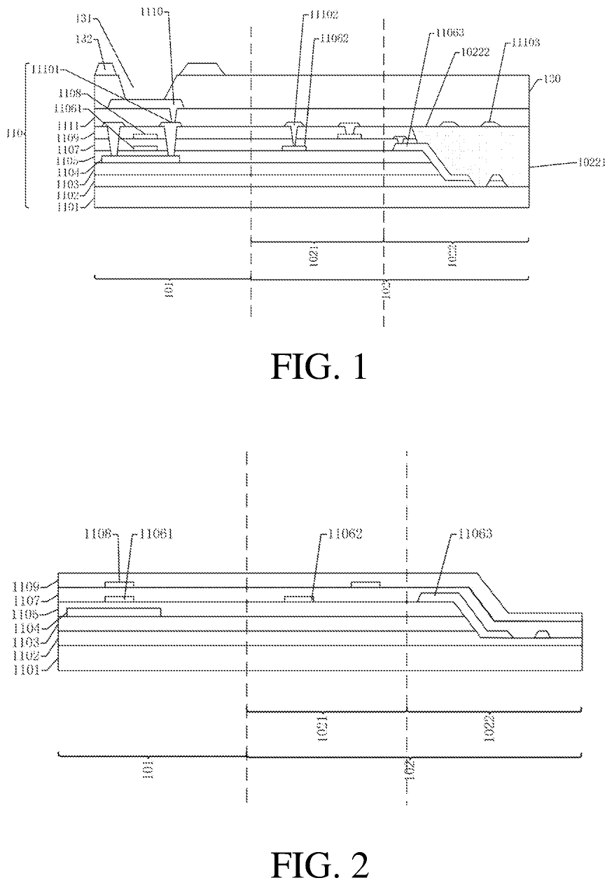

As shown in FIG. 1, the thin-film transistor layer 110 includes a substrate 1101, a barrier layer 1102, a buffer layer 1103, an active layer 1104, a first insulating layer 1105, a first gate layer 1106, a second insulating layer 1107, a second gate layer 1108, a third insulating layer 1109, a source-drain electrode layer 1110, and a planarization layer 1111.

The barrier layer 1102 is disposed on the substrate 1101. A material of the barrier layer 1102 includes one or more of silicon oxide, silicon nitride, silicon oxynitride, and amorphous silicon, and is mainly used to block water and oxygen to prevent water and oxygen from corroding the array substrate.

The buffer layer 1103 is disposed on the barrier layer 1102. The buffer layer 1103 is made of an insulating material, and acts as a buffer while preventing short circuiting of an electrode layer subsequently formed on the buffer layer 1103.

The array substrate of the present invention further includes a display area 101 and a non-display area 102 surrounding the display area 101. The non-display area 102 has a bonding area 1022 and a fan-out area 1021 positioned between the bonding area 1022 and the display area 102.

The active layer 1104 is disposed on the buffer layer 1103, and the first insulating layer 1105 is disposed on the buffer layer 1103 and covers the active layer 1104.

The first gate layer 1106 is disposed on the first insulating layer 1105. Specifically, the first gate layer 1106 includes a first metal segment 11061, a second metal segment 11062, and a third metal segment 11063.

The first metal segment 11061 is disposed in the display area 101 and corresponds to the active layer 1104, the second metal segment 11062 is disposed in the fan-out area 1021, and the third metal segment 11063 is disposed in the bonding area 1022.

An opening 10221 is formed in the bonding area 1022, and the opening 10221 penetrates through the third insulating layer 1109, the second insulating layer 1107, the first insulating layer 1105, the buffer layer 1103, and a portion of the barrier layer 1102. A thickness of the barrier layer 1102 that is not penetrated by the opening 10221 is less than 5000 A. The third metal segment 11063 extends from the first insulating layer 1105 to the opening 10221 and covers an inner wall of the opening 10221.

The second insulating layer 1107 covers the first gate layer 1106 and extends from the display area 101 to an edge of the opening 1021 in the bonding area 1022.

The second gate layer 1108 is disposed on the second insulating layer 1107. Specifically, in the display area 101, the fan-out area 1021, and the bonding area 1022, each of the first metal segment 11061, the second metal segment 11062, and the third metal segment 11063 of the first gate layer 1106 has a segment corresponding to the second gate layer 1108 and is used to connect to the source-drain electrode layer.

The third insulating layer 1109 covers the second gate layer 1108 and extends from the display area 101 to an edge of the opening 10221 in the bonding area 1022.

The source-drain electrode layer 1110 includes a first source-drain electrode layer 11101, a second source-drain electrode layer 11102, and a third source-drain electrode layer 11103.

The first source-drain electrode layer 11101 is disposed on the third insulating layer 1109 of the display area 101. The first source-drain electrode layer 11101 is provided with two pins. The pins penetrate through the third insulating layer 1109, the second insulating layer 1107, and the first insulating layer 1105 in order until they are connected to the active layer 1104.

The second source-drain electrode layer 11102 is disposed on the third insulating layer 1109 in the fan-out area 1021. The second source-drain electrode layer 11102 is provided with two pins, one of which is connected to the second gate layer 1108 through the third insulating layer 1109, while the other pin penetrates the third insulating layer 1109 and the second insulating layer 1107 and is connected to the second metal segment 11062.

The opening 10221 is filled with an organic substance to form an organic layer 10222. The organic layer 10222 is flush with the third insulating layer 1109 on the side far from the second insulating layer 1107. The third source-drain electrode layer 11103 is disposed on the organic layer 10222. In the bonding area 1022, the third metal segment 11063 and the second gate layer 1108 are disposed below the organic layer 10222, which is closer to the neutral plane and reduces the risk of disconnection in the bonding area 1022.

In the present embodiment, the first gate layer 1106, the second gate layer 1108, and the source-drain electrode layer 1110 are made of the same materials, which are low-resistance and bend-resistant metals, such as aluminum, titanium, titanium aluminum alloy. This improves the electrical conductivity and bending resistance of the first gate layer 1106, the second gate layer 1108, and the source-drain electrode layer 1110.

The planarization layer 1111 is disposed on the third insulating layer 1109 and covers the source-drain electrode layer 1110.

The anode layer 120 is disposed in the display area 101. Specifically, the anode layer 120 is disposed on the planarization layer 1111 and corresponds to the first source-drain electrode layer 11101. The anode layer 120 includes a pin, and the pin penetrates the planarization layer 1111 and is connected to the first source-drain electrode layer 11101.

The pixel definition layer 130 is disposed on the planarization layer 1111. Specifically, the pixel definition layer 130 is provided with a pixel opening 131 corresponding to the anode layer 120 for carrying ink in an subsequent inkjet printing process, and retaining walls 132 are also provided on both sides of the pixel opening 131 to prevent ink from overflowing in the subsequent inkjet printing process.

In order to better explain the present invention, in the present embodiment, a method of manufacturing the array substrate of the present invention includes:

Step 1, forming a thin-film transistor structure layer, wherein the thin-film transistor structure layer includes a gate layer and a source-drain electrode layer, and material of the gate layer and the source-drain electrode layer includes at least one of titanium, aluminum, or titanium aluminum alloy. Specific steps of manufacturing the thin-film transistor structure layer are as follows:

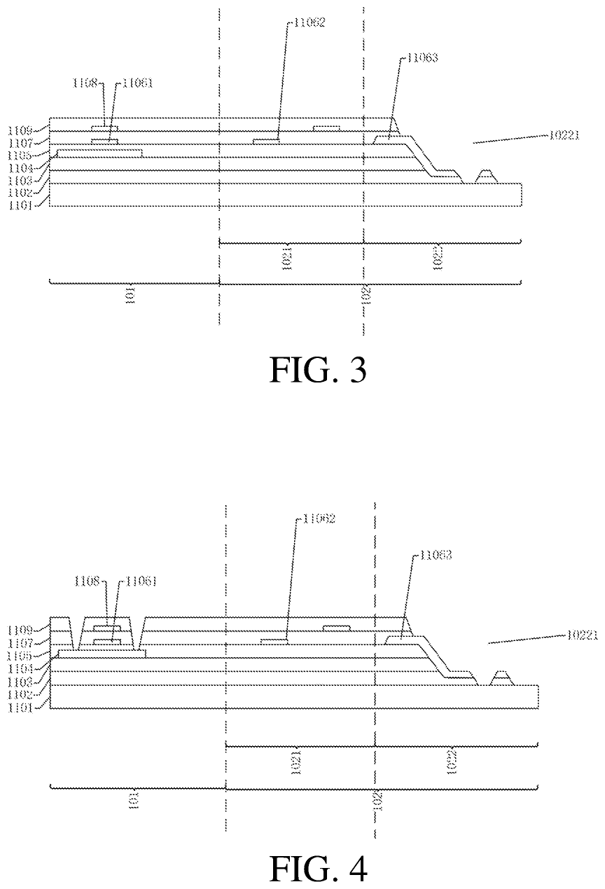

Step 101, providing a substrate; Step 102, depositing a barrier layer on the substrate; Step 103, depositing a buffer layer on the barrier layer; Step 104, forming an active layer and a first insulating layer on the buffer layer in the display area, wherein the first insulating layer covers the active layer and extends to the non-display area; Step 105, forming an opening by etching in the bonding area, wherein the opening penetrates through the first insulating layer, the buffer layer, and a portion of the barrier layer in the bonding area; Step 106, forming a metal layer on the first insulating layer and etching to form a second gate layer, wherein forming the metal layer includes forming a first metal segment on the display area corresponding to the active layer, forming a second metal segment in the fan-out area and forming a third metal segment in the bonding area, and forming a metal trace by etching. The third metal segment extends from the first insulating layer and covers an inner wall of the opening; Step 107, depositing a second insulating layer on the first insulating layer, wherein the second insulating layer covers the first gate layer and extends to the non-display area; Step 108, forming a second metal layer on the second insulating layer and etching to form a second gate layer; Step 109, as shown in FIG. 2, depositing a third insulating layer on the second insulating layer, wherein the third insulating layer covers the second gate layer and extends to the non-display area; Step 110, as shown in FIG. 3, etching the second insulating layer and the third insulating layer at a position corresponding to the opening in the bonding area, at the same time using the third metal segment at the bottom of the opening as a mask to pattern the barrier layer, and filling the opening after etching with an organic substance to form an organic layer. This not only saves cost of the mask but also solves the problem of poor adhesion of metal trace on the etched flexible substrate; Step 111, forming a first via-hole by etching the third insulating layer, the second insulating layer, and the first insulating layer at a position corresponding to the active layer in the display area, and forming a second via-hole by etching the third insulating layer and the second insulating layer in the fan-out area; Step 112, depositing a first source-drain electrode layer on the third insulating layer corresponding to the first via-hole, wherein the first source-drain electrode layer is electrically connected to the active layer through the first via-hole, depositing a second source-drain electrode layer corresponding to the second via-hole, wherein the second source-drain electrode layer is electrically connected to the first gate layer and the second gate layer through the second via-hole, and forming a third source-drain electrode layer on the organic layer in the bonding area; and Step 113, forming a planarization layer on the third insulating layer and extending the planarization layer to the non-display area.

As shown in FIG. 4, in another preferred embodiment of the present invention, the method of manufacturing an array substrate may further replace step 110 with: Etching the second insulating layer and the third insulating layer corresponding to the opening in the bonding area, and simultaneously forming a first via-hole by etching the third insulating layer, the second insulating layer, and the first insulating layer at a position corresponding to the active layer in the display area, and forming a second via-hole by etching the third insulating layer and the second insulating layer in the fan-out area.

The step S111 is replaced with: Forming an organic layer by filling the opening after etching with an organic substance. The method of manufacturing the array substrate further includes: Step 2, forming a via-hole on the planarization layer corresponding to the first source-drain electrode layer and depositing an anode layer on the planarization layer, and connecting the anode layer to the first source-drain electrode layer through the via-hole; Step 3, depositing a pixel definition layer on the planarization layer, wherein the pixel definition layer covers the anode layer; and Step 4, forming a light-emitting hole in the pixel definition layer corresponding to an area of the anode layer, wherein a bottom surface of the light-emitting hole is completely disposed on the anode layer.

### Embodiment 2

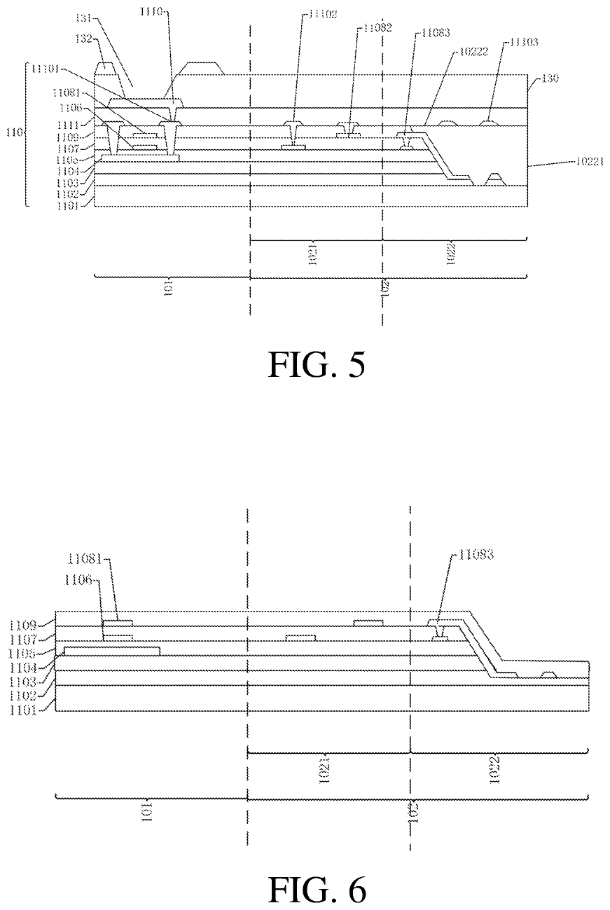

As shown in FIG. 5, in the present embodiment, an array substrate of the present invention is substantially similar in structure to the array substrate in embodiment 1, the difference is that the second gate layer 1108 in the array substrate in the present embodiment includes a fourth metal segment 11081, a fifth metal segment 11082, and a sixth metal segment 11083. The fourth metal segment 11081 is disposed on the second insulating layer 1107 in the display area 101 and corresponds to the active layer 1104. The fifth metal segment 11082 is disposed in the fan-out area 1021. The sixth metal segment 11083 is disposed in the bonding area 1022, wherein the first gate layer 1106 is disposed on the first insulating layer 1105 and corresponds to the second gate layer 1108.

An opening 10221 is formed in the bonding area 1022, and the opening 10221 penetrates through the third insulating layer 1109, the second insulating layer 1107, the first insulating layer 1105, the buffer layer 1103, and a portion of the barrier layer 1102. The thickness of the barrier layer 1102 that is not penetrated by the opening 10221 is less than 5000 A. The sixth metal segment 11083 extends from the second insulating layer 1107 to the opening 10221 and covers an inner wall of the opening 10221.

In order to better explain the present invention, in the present embodiment, a method of manufacturing the array substrate of the present invention includes: Step 1, forming a thin-film transistor structure layer, wherein the thin-film transistor structure layer includes a gate layer and a source-drain electrode layer, and material of the gate layer and the source-drain electrode layer includes at least one of titanium, aluminum, or titanium aluminum alloy.

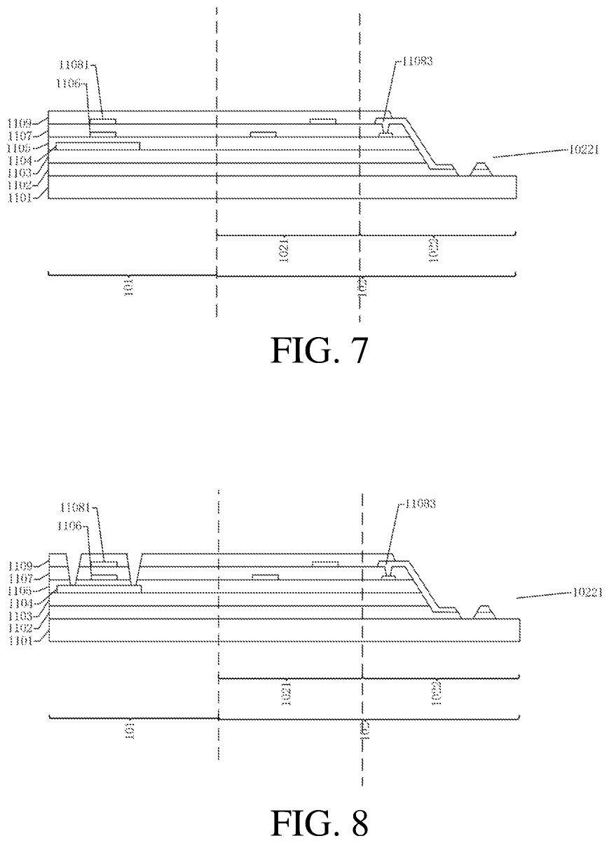

In the step 1, specific manufacturing steps of the thin-film transistor structure layer includes: Step 101, providing a substrate; Step 102, depositing a barrier layer on the substrate; Step 103, depositing a buffer layer on the barrier layer; Step 104, forming an active layer and a first insulating layer on the buffer layer in the display area, wherein the first insulating layer covers the active layer and extends to the non-display area; Step 105, forming a first gate layer on the first insulating layer; Step 106, depositing a second insulating layer on the first insulating layer, wherein the second insulating layer covers the first gate layer and extends to the non-display area; Step 107, forming an opening by etching in the bonding area, wherein the opening penetrates the second insulating layer, the first insulating layer, the buffer layer, and a portion of the barrier layer in the bonding area; Step 108, forming a second gate layer on the second insulating layer, wherein forming the second gate layer includes forming a fourth metal segment on the display area corresponding to the active layer, forming a fifth metal segment in the fan-out area, and forming a sixth metal segment in the bonding area, the sixth metal segment covering the inner wall of the opening from the second insulating layer; Step 109, as shown in FIG. 6, depositing a third insulating layer on the second insulating layer, wherein the third insulating layer covers the second gate layer and extends to the non-display area; Step 110, as shown in FIG. 7, etching the third insulating layer at a position corresponding to the opening in the bonding area, and filling the opening after etching with an organic substance to form an organic layer; Step 111, forming a first via-hole by etching the third insulating layer, the second insulating layer, and the first insulating layer at a position corresponding to the active layer in the display area, and forming a second via-hole by etching the third insulating layer and the second insulating layer in the fan-out area; Step 112, depositing a first source-drain electrode layer on the third insulating layer corresponding to the first via-hole, wherein the first source-drain electrode layer is electrically connected to the active layer through the first via-hole, depositing a second source-drain electrode layer corresponding to the second via-hole, wherein the second source-drain electrode layer is electrically connected to the first gate layer and the second gate layer through the second via-hole, and forming a third source-drain electrode layer on the organic layer in the bonding area; and Step 113, forming a planarization layer on the third insulating layer and extending the planarization layer to the non-display area.

As shown in FIG. 8, in another preferred embodiment of the present invention, the method of manufacturing the array substrate can further replace step S110 with: Etching the second insulating layer and the third insulating layer corresponding to the opening in the bonding area, and simultaneously forming a first via-hole by etching the third insulating layer, the second insulating layer, and the first insulating layer at a position corresponding to the active layer in the display area, and forming a second via-hole by etching the third insulating layer and the second insulating layer in the fan-out area.

The step S111 is replaced with: Forming an organic layer by filling the opening after etching with an organic substance.

The method of manufacturing the array substrate further includes: Step 2, forming a via-hole on the planarization layer corresponding to the first source-drain electrode layer and depositing an anode layer on the planarization layer, and connecting the anode layer to the first source-drain electrode layer through the via-hole; Step 3, depositing a pixel definition layer on the planarization layer, wherein the pixel definition layer covers the anode layer; and Step 4, forming a light-emitting hole in the pixel definition layer corresponding to an area of the anode layer, wherein a bottom surface of the light-emitting hole is completely disposed on the anode layer.

The description above is only preferred embodiments of the present invention and is not intended to limit the present invention. Any modification, equivalent replacement, and improvement made within the spirit and principle of the present invention should be included in the protection scope of the present invention.

What is claimed is:

1. An array substrate, wherein the array substrate comprises a display area and a non-display area surrounding the display area, the non-display area has a bonding area and a fan-out area positioned between the bonding area and the display area, further comprising:
a thin-film transistor structure layer comprising a gate layer and a source-drain electrode layer, wherein material of the gate layer and the source-drain electrode layer comprises at least one of titanium, aluminum, or titanium aluminum alloy.

2. The array substrate according to claim 1, wherein the thin-film transistor structure layer comprises:
a substrate extending from the display area to the non-display area;
a barrier layer disposed on the substrate and extending from the display area to the non-display area;
a buffer layer disposed on the barrier layer and extending from the display area to the non-display area;
an active layer disposed on the buffer layer of the display area;
a first insulating layer disposed on the buffer layer and covering the active layer and extending to the non-display area, the gate layer comprising a first gate layer and a second gate layer, wherein the first gate layer is disposed on the first insulating layer;
a second insulating layer disposed on the first insulating layer and covering the first gate layer and extending to the non-display area, wherein the second gate layer is disposed on the second insulating layer;
a third insulating layer disposed on the second insulating layer and covering the second gate layer and extending to the non-display area; the source-drain electrode layer comprising a first source-drain electrode layer disposed on the third insulating layer of the display area and penetrating the third insulating layer, the second insulating layer, and the first insulating layer, and connecting to the active layer; and
a second source-drain electrode layer disposed on the third insulating layer in the fan-out area and penetrating the third insulating layer and the second insulating layer, and connecting to the first gate layer and the second gate layer;
an opening defined in the bonding area, wherein the opening penetrates the third insulating layer, the second insulating layer, the first insulating layer, the buffer layer, and a portion of the barrier layer; and
a planarization layer disposed on the third insulating layer and covering the source-drain electrode layer and extending to the non-display area.

3. The array substrate according to claim 2, wherein the first gate layer comprises:
a first metal segment disposed in the display area and corresponding to the active layer;
a second metal segment disposed on the first insulating layer in the fan-out area; and
a third metal segment disposed in the bonding area and extending from the first insulating layer to an inner wall of the opening.

4. The array substrate according to claim 2, wherein the second gate layer comprises:
a fourth metal segment disposed in the display area and corresponding to the active layer;
a fifth metal segment disposed on the second insulating layer in the fan-out area; and
a sixth metal segment disposed in the bonding area and extending from the second insulating layer to an inner wall of the opening.

5. A method of manufacturing an array substrate, wherein the array substrate comprises a display area and a non-display area surrounding the display area, the non-display area has a bonding area and a fan-out area positioned between the bonding area and the display area, comprising:
Step 1, forming a thin-film transistor structure layer, wherein the thin-film transistor structure layer comprises a gate layer and a source-drain electrode layer, and material of the gate layer and the source-drain electrode layer comprises at least one of titanium, aluminum, or titanium aluminum alloy.

6. The method of manufacturing the array substrate according to claim 5, wherein in the step 1, specific manufacturing steps of the thin-film transistor structure layer comprise:
Step 101, providing a substrate;
Step 102, depositing a barrier layer on the substrate;
Step 103, depositing a buffer layer on the barrier layer;
Step 104, forming an active layer and a first insulating layer on the buffer layer in the display area, wherein the first insulating layer covers the active layer and extends to the non-display area;
Step 105, forming an opening by etching in the bonding area, the opening penetrating through the first insulating layer, the buffer layer, and a portion of the barrier layer in the bonding area;
Step 106, forming a first gate layer on the first insulating layer, wherein forming the first gate layer comprises forming a first metal segment on the display area corresponding to the active layer, forming a second metal segment in the fan-out area, and forming a third metal segment in the bonding area, the third metal segment extending from the first insulating layer and covering the inner wall of the opening;
Step 107, depositing a second insulating layer on the first insulating layer, wherein the second insulating layer covers the first gate layer and extends to the non-display area;
Step 108, forming a second gate layer on the second insulating layer;
Step 109, depositing a third insulating layer on the second insulating layer, wherein the third insulating layer covers the second gate layer and extends to the non-display area;
Step 110, etching the second insulating layer and the third insulating layer at a position corresponding to the opening in the bonding area, and filling the opening after etching with an organic substance to form an organic layer;
Step 111, forming a first via-hole by etching the third insulating layer, the second insulating layer, and the first insulating layer at a position corresponding to the active layer in the display area, and forming a second via-hole by etching the third insulating layer and the second insulating layer in the fan-out area;
Step 112, depositing a first source-drain electrode layer on the third insulating layer corresponding to the first via-hole, wherein the first source-drain electrode layer is electrically connected to the active layer through the first via-hole, depositing a second source-drain electrode layer corresponding to the second via-hole, wherein the second source-drain electrode layer is electrically connected to the first gate layer and the second gate layer through the second via-hole, and forming a third source-drain electrode layer on the organic layer in the bonding area; and
Step 113, forming a planarization layer on the third insulating layer and extending the planarization layer to the non-display area.

7. The method of manufacturing the array substrate according to claim 5, comprising:
Step 101, providing a substrate;
Step 102, depositing a barrier layer on the substrate;
Step 103, depositing a buffer layer on the barrier layer;
Step 104, forming an active layer and a first insulating layer on the buffer layer in the display area, wherein the first insulating layer covers the active layer and extends to the non-display area;
Step 105, forming an opening by etching in the bonding area, the opening penetrating the first insulating layer, the buffer layer, and a portion of the barrier layer in the bonding area;
Step 106, forming a first gate layer on the first insulating layer, wherein forming the first gate layer comprises forming a first metal segment corresponding to the active layer in the display area, forming a second metal segment in the fan-out area, and forming a third metal segment in the bonding area, the third metal segment covering an inner wall of the opening from the first insulating layer;
Step 107, depositing a second insulating layer on the first insulating layer, wherein the second insulating layer covers the first gate layer and extends to the non-display area;
Step 108, forming a second gate layer on the second insulating layer;
Step 109, depositing a third insulating layer on the second insulating layer, wherein the third insulating layer covers the second gate layer and extends to the non-display area;
Step 110, etching the second insulating layer and the third insulating layer at a position corresponding to the opening in the bonding area and simultaneously etching the third insulating layer, the second insulating layer, and the first insulating layer at a position corresponding to the active layer in the display area to form a first via-hole, and etching the third insulating layer and the second insulating layer in the fan-out area to form a second via-hole;
Step 111, filling the opening after etching with an organic substance to form an organic layer;
Step 112, depositing a first source-drain electrode layer on the third insulating layer at a position corresponding to the first via-hole, wherein the first source-drain electrode layer is electrically connected to the active layer through the first via-hole, depositing a second source-drain electrode layer at a position corresponding to the second via-hole, wherein the second source-drain electrode layer is electrically connected to the first gate layer and the second gate layer through the second via-hole, and forming a third source-drain electrode layer on the organic layer in the bonding area; and
Step 113, forming a planarization layer on the third insulating layer and extending to the non-display area.

8. The method of manufacturing the array substrate according to claim 5, wherein in the step 1, specific manufacturing steps of the thin-film transistor structure layer comprise:
Step 101, providing a substrate;
Step 102, depositing a barrier layer on the substrate;
Step 103, depositing a buffer layer on the barrier layer;
Step 104, forming an active layer and a first insulating layer on the buffer layer in the display area, wherein the first insulating layer covers the active layer and extends to the non-display area;
Step105, forming a first gate layer on the first insulating layer;
Step 106, depositing a second insulating layer on the first insulating layer, wherein the second insulating layer covers the first gate layer and extends to the non-display area;
Step 107, forming an opening by etching in the bonding area, the opening penetrating through the second insulating layer, the first insulating layer, the buffer layer, and a portion of the barrier layer in the bonding area;
Step 108, forming a second gate layer on the second insulating layer, wherein forming the second gate layer comprises forming a fourth metal segment on the display area corresponding to the active layer, forming a fifth metal segment in the fan-out area, and forming a sixth metal segment in the bonding area, the sixth metal segment covering an inner wall of the opening from the second insulating layer;
Step 109, depositing a third insulating layer on the second insulating layer, wherein the third insulating layer covers the second gate layer and extends to the non-display area;
Step 110, etching the third insulating layer at a position corresponding to the opening in the bonding area, and filling the opening after etching with an organic substance to form an organic layer;
Step 111, forming a first via-hole by etching the third insulating layer, the second insulating layer, and the first insulating layer at a position corresponding to the active layer in the display area, and forming a second via-hole by etching the third insulating layer and the second insulating layer in the fan-out area;
Step 112, depositing a first source-drain electrode layer on the third insulating layer corresponding to the first via-hole, wherein the first source-drain electrode layer is electrically connected to the active layer through the first via-hole, depositing a second source-drain electrode layer corresponding to the second via-hole, wherein the second source-drain electrode layer is electrically connected to the first gate layer and the second gate layer through the second via-hole, and forming a third source-drain electrode layer on the organic layer in the bonding area; and
Step 113, forming a planarization layer on the third insulating layer and extending the planarization layer to the non-display area.

9. The method of manufacturing the array substrate according to claim 5, wherein in the step 1, specific manufacturing steps of the thin-film transistor structure layer comprise:
Step 101, providing a substrate;
Step 102, depositing a barrier layer on the substrate;
Step 103, depositing a buffer layer on the barrier layer;
Step 104, forming an active layer and a first insulating layer on the buffer layer in the display area, wherein the first insulating layer covers the active layer and extends to the non-display area;
Step 105, forming a first gate layer on the first insulating layer;
Step 106, depositing a second insulating layer on the first insulating layer, wherein the second insulating layer covers the first gate layer and extends to the non-display area;
Step 107, forming an opening by etching in the bonding area, the opening penetrating through the second insulating layer, the first insulating layer, the buffer layer, and a portion of the barrier layer in the bonding area;
Step 108, forming a second gate layer on the second insulating layer, wherein forming the second gate layer comprises forming a fourth metal segment on the display area corresponding to the active layer, forming a fifth metal segment in the fan-out area, and forming a sixth metal segment in the bonding area, the sixth metal segment covering an inner wall of the opening from the second insulating layer;
Step 109, depositing a third insulating layer on the second insulating layer, wherein the third insulating layer covers the second gate layer and extends to the non-display area;
Step 110, etching the third insulating layer at a position corresponding to the opening in the bonding area and simultaneously etching the third insulating layer, the second insulating layer, and the first insulating layer at a position corresponding to the active layer in the display area to form a first via-hole, and etching the third insulating layer and the second insulating layer in the fan-out area to form a second via-hole;
Step 111, filling the opening after etching with an organic substance to form an organic layer;
Step 112, depositing a first source-drain electrode layer on the third insulating layer at a position corresponding to the first via-hole, wherein the first source-drain electrode layer is electrically connected to the active layer through the first via-hole, depositing a second source-drain electrode layer at a position corresponding to the second via-hole, wherein the second source-drain electrode layer is electrically connected to the first gate layer and the second gate layer through the second via-hole, and forming a third source-drain electrode layer on the organic layer in the bonding area; and
Step 113, forming a planarization layer on the third insulating layer and extending to the non-display area.

10. The method of manufacturing the array substrate according to claim 6, further comprising:
Step 2, forming a via-hole on the planarization layer corresponding to the first source-drain electrode layer and depositing an anode layer on the planarization layer, wherein the anode layer is connected to the first source-drain electrode layer through the via-hole;
Step 3, depositing a pixel definition layer on the planarization layer, wherein the pixel definition layer covers the anode layer; and
Step 4, forming a light-emitting hole in the pixel definition layer corresponding to an area of the anode layer, wherein a bottom surface of the light-emitting hole is completely disposed on the anode layer.

11. The method of manufacturing the array substrate according to claim 8, further comprising:
Step 2, forming a via-hole on the planarization layer corresponding to the first source-drain electrode layer and depositing an anode layer on the planarization layer, wherein the anode layer is connected to the first source-drain electrode layer through the via-hole;
Step 3, depositing a pixel definition layer on the planarization layer, wherein the pixel definition layer covers the anode layer; and
Step 4, forming a light-emitting hole in the pixel definition layer corresponding to an area of the anode layer, wherein a bottom surface of the light-emitting hole is completely disposed on the anode layer.
